(19) United States
(12) Patent Application Publication
(10) Pub. No.: US 2007/0098623 A1
(43) Pub. Date: May 3, 2007

(54) Method for manufacturing carbon nanotubes

(75) Inventor: Chi-Chuang Ho, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/434,373

(22) Filed: May 15, 2006

(30) Foreign Application Priority Data
Oct. 27, 2005 (CN) 200510100771.9

(51) Int. Cl. B05D 3/12; C23C 16/00; D01F 9/12

(52) U.S. Cl. 423/447.3; 427/240; 427/249.1

(57) ABSTRACT

A method for manufacturing carbon nanotubes includes the steps of: providing at least one substrate (40) having a first surface (40a) and an opposite second surface (40b); spin coating magnetic fluid (302) on the first surface and the second surface of the at least one substrate thereby forming first and second catalytic layers (42a, 42b) on the respective first surface and second surface; growing carbon nanotubes on the first and second surfaces of the at least one surface by a chemical vapor deposition method.

### TECHNICAL FIELD

The present invention generally relates to methods for manufacturing carbon nanotubes. Specifically, the present invention relates to a method for manufacturing carbon nanotubes by chemical vapor deposition (CVD) using magnetic fluid.

### BACKGROUND

Carbon nanotubes produced by arc discharge between graphite rods were first discovered and reported in an article by Sumio Iijima entitled “Helical Microtubules of Graphitic Carbon” (Nature, Vol. 354, Nov. 7, 1991, pp. 56-58).

Carbon nanotubes are electrically conductive along their length, are chemically stable, and can have very small diameters (much less than 100 nanometers) and large aspect ratios (length/diameter). Due to these and other properties, it has been suggested that carbon nanotubes can play an important role in fields such as microscopic electronics, field emission devices, thermal interface materials, etc.

The manufacture of carbon nanotubes has three main methods: arc-discharge, laser ablation, and chemical vapor deposition.

The arc-discharge method is performed in a stainless steel chamber. Two graphite rods are used as an anode and a cathode. A DC (Direct Current) voltage is applied between the two graphite rods. The arc-discharge between the two graphite rods deposits carbon nanotubes which grow on the cathode. However, the purity of the carbon nanotubes is low so that it is not suitable for mass production of carbon nanotubes. Therefore, a purification step is needed for high purity of carbon nanotubes.

The laser ablation method is performed by vaporizing carbon using laser impinging on a metal-graphite composite target. The vaporized carbon is swept up with a gas-flow and deposited onto a surface of a water-cooled copper collector positioned downstream thus growing carbon nanotubes. Purity of carbon nanotubes, especially single wall carbon nanotubes (SWCNTs), is high. However, productivity of SWCNTs is low so that it is not suitable for mass production.

The chemical vapor deposition (CVD) method involves manufacture of carbon nanotubes by a catalytic decomposition of hydrocarbons onto a metallic layer, made of a substance such as iron (Fe), cobalt (Co), nickel (Ni) or any appropriate alloy thereof. Since the CVD allows easier control of manufacturing carbon nanotubes and large area manufacture, the CVD is used widely to manufacture carbon nanotubes. However, in a conventional CVD method, a metallic layer must be deposited onto a substrate by sputtering or evaporation for forming a catalytic layer. Due to cost of the deposition system for the metallic layer is high and the deposition system is operationally complicated, it therefore is not a cheap process with which to manufacture carbon nanotubes.

What is needed, therefore, is a cheaper method with which to manufacture carbon nanotubes.

### SUMMARY

In a preferred embodiment, a method for manufacturing carbon nanotubes includes the steps of: providing at least one substrate having a first surface and an opposite second surface; spin coating magnetic fluid onto the first surface and the second surface of the at least one substrate thereby forming first and second catalytic layers on the respective first and second surfaces; growing carbon nanotubes on the first and second surfaces of the at least one substrate by a chemical vapor deposition method.

Cost of manufacturing carbon nanotubes is reduced due to simplicity and low cost of the spin-coating technique.

Other advantages and novel features will become more apparent from the following detailed description of the present method, when taken in conjunction with the accompanying drawings.

### BRIEF DESCRIPTION OF THE DRAWINGS

Many aspects of the present method for manufacturing carbon nanotubes can be better understood with reference to the following drawings. The components in the drawings are not necessarily drawn to scale, the emphasis instead being placed upon clearly illustrating the principles of the present method for manufacturing carbon nanotubes. Moreover, in the drawings, like reference numerals designate corresponding parts throughout the several views.

FIG. 1 is a schematic view of a substrate fixed onto a spin-coating device in accordance with a preferred embodiment,

FIG. 2 is similar to FIG. 1, showing a catalytic layer spin coated on a surface of the substrate of FIG. 1;

FIG. 3 is a schematic, sectional view of the substrate with the catalytic layers thereon in accordance with the preferred embodiment.

FIG. 4 is a schematic, sectional view of the substrate with catalytic layers placed into a chemical vapor deposition chamber in accordance with the preferred embodiment; and

FIG. 5 is a schematic, sectional view of a plurality of substrates with catalytic layers placed into a chemical vapor deposition chamber in accordance with the preferred embodiment.

Corresponding reference characters indicate corresponding parts throughout the drawings. The exemplifications set out herein illustrate at least one preferred embodiment of the present method for manufacturing carbon nanotubes, in one form, and such exemplifications are not to be construed as limiting the scope of the invention in any manner.

### DETAILED DESCRIPTION OF PREFERRED EMBODIMENTS

Reference will now be made to the drawings to describe preferred embodiments of the present method for manufacturing carbon nanotubes, in detail.

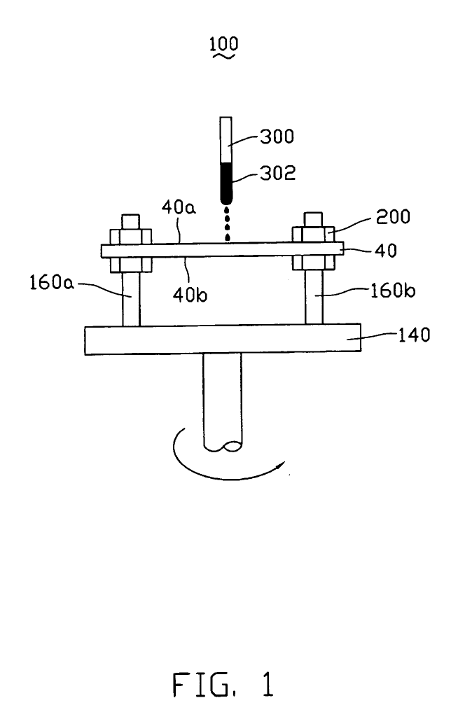

Referring to FIGS. 1 to 5, successive steps of a method for manufacturing carbon nanotubes, in accordance with a preferred embodiment, are shown. The method includes the following steps:

(1) providing a substrate 40 having a first surface 40a and an opposite surface 40b;

(2) spin coating magnetic fluid 302 onto the first surface 40a and the second surface 40b of the substrate 40 thereby forming a first catalytic layer 42a and a second catalytic layer 42b on the respective first surface 40a and second surface 40b;

(3) growing carbon nanotubes on the first surface 40a and second surface 40b of the substrate 40 by a chemical vapor deposition method.

In step (1), a material of the substrate 40 is selected from the group consisting of silicon, quartz and glass.

Referring to FIG. 1, in step (2), a spin-coating device 100 is provided. The spin-coating device 100 includes a rotary plate 140 and a pair of positioning posts 160a, 160b extending from the rotary plate 140. The rotary plate 140 rotates centrifugally with the pair of the positioning posts 160a, 160b when working.

The substrate 40 is attached to the spin-coating device 100 by extension of the pair of positioning post 160a, 160b through the substrate 40 in a manner that the second surface 40b of the substrate 40 faces the rotary plate 140. In this preferred embodiment, the substrate 40 is attached to the spin-coating device 100 by matching screw caps 200 with screw threads on the pair of positioning posts 160a, 160b. The spin-coating device 100 drives the rotary plate 140 to rotate. The magnetic fluid 302 is injected onto the first surface 40a of the substrate 40 by an injecting device 300. A magnetic fluid layer is spin coated uniformly on the first surface 40a, thereby a first catalytic layer 42a is formed on the first surface 40a of the substrate 40.

Preferably, the substrate 40 is rotated at a speed in the range from 1000 to 5000 revolutions per minute (rpm). The magnetic fluid 302 mainly contains a solvent, magnetic nanoparticals dispersed in the solvent, and a surfactant. The magnetic nanoparticals are selected from the group consisting of ferroso-ferric oxide (Fe₃O₄) nanoparticals, ferrite nanoparticals, iron (Fe) nanoparticals, cobalt (Co) nanoparticals, nickel (Ni) nanoparticals and mixture thereof. The ferrite nanoparticals include Co-substituted magnetite (CoFe₂O₄) nanoparticals and Ni-substituted magnetite (NiFe₂O₄) nanoparticals. Grain size of the magnetic nanoparticals is in the range from 10 to 100 nanometers. The solvent is selected from the group consisting of organic solvent, such as heptane, xylene, toluene and acetone, hydrocarbon, synthetic ester, polyglycols, halogenated hydrocarbon, styrene, or pure water. The surfactant may be capric acid (CH₃(CH₂)₈COOH). Preferably, a thickness of the first catalytic layer 42a is in the range from 100 to 900 nanometers.

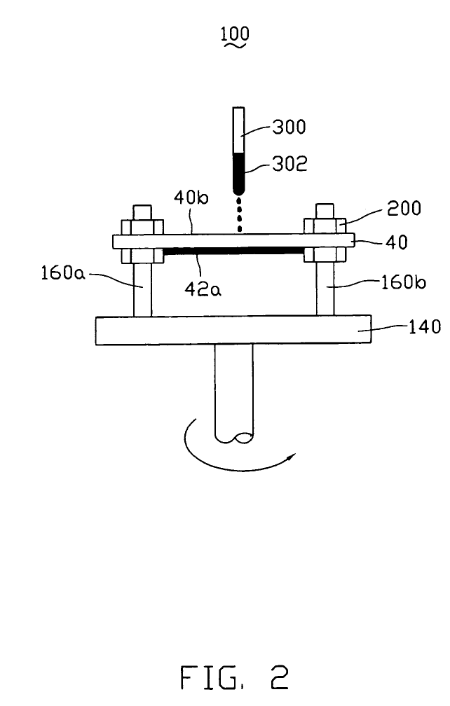

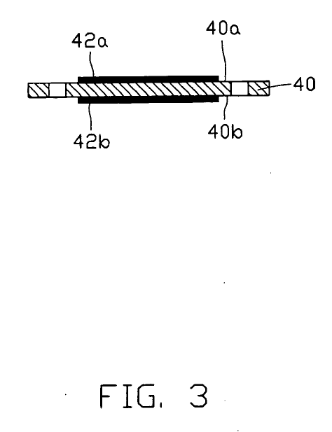

Referring to FIGS. 2 and 3, the substrate 40 is reversed so as to let the first surface 40a with the first catalytic layer 42a face the rotary plate 140 and then be attached to the spin-coating device 100 in a manner such that a space is kept between the substrate 40 and the rotary plate 140. Then a second catalytic layer 42b is formed on the second surface 40b by spin coating. Therefore, the substrate 40 having two surfaces with the catalytic layers 42a and 42b is formed according to FIG. 3. Preferably, a thickness of the second catalytic layer 40b is in the range from 100 to 900 nanometers. Damage to the formed first catalytic layer 42a can be avoided due to the space between the substrate 40 and the rotary plate 140.

In order to avoid clumping of the coated magnetic fluid 302 on the first surface 40a and the second surface 40b on the substrate 40, the magnetic fluid 302 further contains a binder, such as poly(vinyl alcohol) (PVA) to adjust a viscosity of the magnetic fluid 302 so as to form the uniform catalytic layers 42a and 42b.

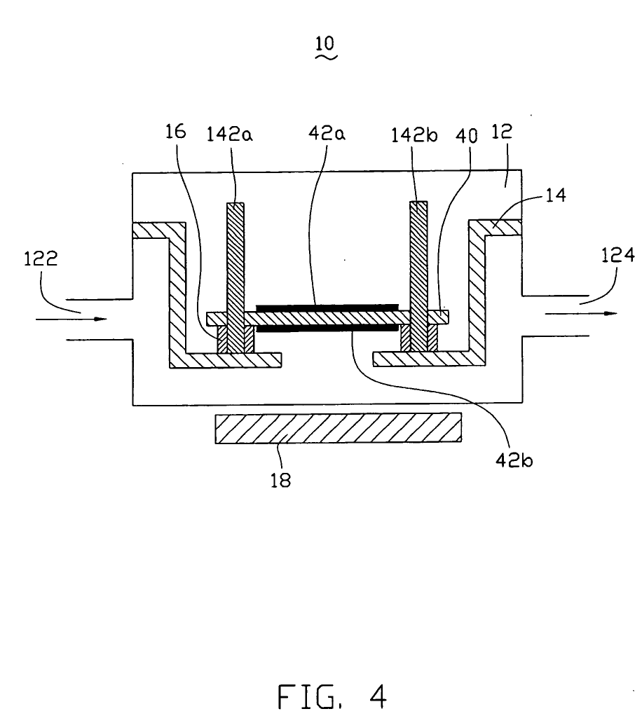

Referring to FIG. 4, in step (3), carbon nanotubes are manufactured on the substrate 40 with the catalytic layers 42a and 42b by a chemical vapor deposition method. A more detailed description follows.

Firstly, a CVD reactor 10 is provided. The CVD reactor 10 has a chamber 12, a supporting stage 14 and a heating device 18. The chamber 12 includes an inlet 122 and an opposite outlet 124. The inlet 122 and the outlet 124 are arranged in a manner such that a flow direction of carbon-containing gases is perpendicular to or almost perpendicular to a growth direction of carbon nanotubes. The supporting stage 14 has a pair of positioning posts 142a and 142b extending therefrom. The substrate 40 is attached to the supporting stage 14 by extension of the pair of positioned pins 142a and 142b through the substrate 40. Pads 16 are used for keeping space between the supporting stage 14 and the substrate 40 so that damage to the catalytic layer 42b by the supporting stage 14 is avoided. A heating device 18, such as a high-temperature furnace and a high-frequency furnace, etc., is used for heating the catalytic layers 42a and 42b.

Secondly, hydrogen is introduced into the CVD chamber 12 through the inlet 122. Then the catalytic layers 42a and 42b are heated up to a temperature in the range from 800 to 900 degrees centigrade by the heating device 18.

Thirdly, a mixture of carbon-containing gas and ammonia is introduced into the CVD chamber 12 simultaneously. Alternatively, after ammonia introduced into the CVD chamber 12 for five minutes, the carbon-containing gas is introduced into the CVD chamber 12. Then carbon nanotubes grow perpendicularly to or almost perpendicularly to a flowing direction of the mixed gas. The carbon-containing gas is selected from the group consisting of acetylene, ethylene, methane and carbon monoxide. Preferably a flow ratio of the carbon-containing gas to ammonia is in the range from 1:2 to 1:10. The total flow amount of carbon-containing gas and ammonia is in the range from 90 to 200 standard cubic centimeters per minute (sccm).

Finally, after growing carbon nanotubes for 3 to 5 minutes, the carbon-containing gas and ammonia flow is stopped. Inert gas, such as nitrogen and argon, is introduced into the CVD chamber 12 and the substrate 40 is cooled to room temperature. The carbon nanotubes can then be collected.

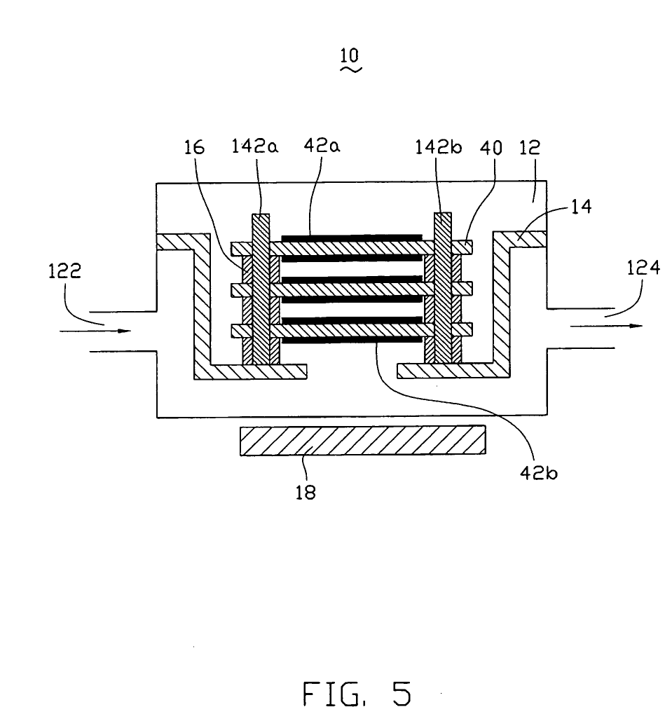

Referring to FIG. 5, a plurality of substrates 40 with catalytic layers 42a and 42b are attached to the supporting stage 14 by extension of the pair of positioning posts 142a and 142b. The plurality of substrates 40 are separated from each other at a certain distance. Carbon nanotubes grow on each substrate 40 so that mass production of carbon nanotubes may be achieved. The distance between the plurality of the substrates 40 is determined by a length of the carbon nanotubes, for example the average distance between neighboring substrates 40 is at least twice longer than the length of the carbon nanotubes. The distance between each plurality of the substrates 40 is set by a plurality of pads 16.

In this preferred embodiment, the catalytic layers 42a and 42b are formed on the substrate 40 by spin coating the magnetic fluid 302 on the first surface 40a and the second surface 40b of the substrate 40. Cost for manufacture of carbon nanotubes is reduced due to simplicity and low cost of the spin-coating technique. Moreover, since two surfaces of the substrate 40 are coated with catalytic layers 42a and 42b, the area for manufacturing carbon nanotubes is doubled. Furthermore, mass production of carbon nanotubes can be achieved by attaching the plurality of substrates 40 to the supporting stage 14 by extension of the pair of positioning posts 142a and 142b.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A method for manufacturing carbon nanotubes, the method comprising the steps of:
providing at least one substrate having a first surface and an opposite second surface;
spin coating magnetic fluid on the first surface and the second surface of the at least one substrate thereby forming first and second catalytic layers on the respective first and second surfaces;
growing carbon nanotubes on the first and second surfaces of the at least one substrate by a chemical vapor deposition method.

2. The method of claim 1, wherein the spin-coating step comprises the steps of:
providing a spin-coating device having a rotary plate and at least one positioning post extending from the rotary plate;
attaching the at least one substrate to the spin-coating device by extension of at least one positioning post through the at least one substrate; and
spin coating the magnetic fluid on the first surface of the at least one substrate thereby forming the first catalytic layer on the first surface of the at least one substrate; and
spin coating the magnetic fluid on the second surface of the at least one substrate thereby forming the second catalytic layer on the second surface of the at least one substrate.

3. The method of claim 1, wherein the at least one substrate comprises a plurality of substrates, and the growing step comprises the step of arranging the substrates in a chemical vapor deposition chamber, the substrates being in parallel with each other.

4. The method of claim 3, wherein the substrates are spaced apart from each other.

5. The method of claim 1, wherein the growing step comprises the steps of:
arranging the at least one substrate in a chemical vapor deposition chamber;
introducing hydrogen gas into the chemical vapor deposition chamber;
heating the catalytic layers up to a temperature in the range from 800 to 900 degrees centigrade; and
introducing a carbon-containing gas into the chemical vapor deposition chamber.

6. The method of claim 1, wherein a thickness of the catalytic layer is in the range from 100 to 900 nanometers.

7. The method of claim 1, wherein in the spin-coating step, the at least one substrate is rotated at a speed in the range from 1000 to 5000 revolutions per minute.

8. The method of claim 1, wherein the magnetic fluid contains a solvent, magnetic nanoparticals dispersed in the solvent, and a surfactant, and a grain size of the magnetic nanoparticals is in the range from 10 to 100 nanometers.

9. The method of claim 8, wherein the magnetic nanoparticals are selected from the group consisting of ferroso-ferric oxide nanoparticals, ferrite nanoparticals, iron nanoparticals, cobalt nanoparticals, nickel nanoparticals and composition thereof.

10. The method of claim 1, wherein the magnetic fluid further contains a binder.

11. The method of claim 10 wherein the binder is poly(vinyl alcohol).
